(19) United States
(12) Patent Application Publication
(10) Pub. No.: US 2024/0355971 A1
(43) Pub. Date: Oct. 24, 2024

(54) DISPLAY PANEL AND JOINABLE DISPLAY PANEL

(71) Applicant: Guangzhou China Star Optoelectronics Semiconductor Display Technology Co., Ltd., Guangzhou (CN)

(72) Inventor: Xiaoping YU, Guangzhou (CN)

(73) Assignee: Guangzhou China Star Optoelectronics Semiconductor Display Technology Co., Ltd., Guangzhou (CN)

(21) Appl. No.: 18/522,349

(22) Filed: Nov. 29, 2023

(30) Foreign Application Priority Data
Apr. 24, 2023 (CN) 202310452906.6

(51) Int. Cl. H01L 33/54; H01L 25/16; H01L 33/50

(52) U.S. Cl. CPC H01L 33/54; H01L 25/167; H01L 33/502

(57) ABSTRACT

A display panel and a joinable display panel are provided. Multiple first pixel units are arranged in a first region and include multiple first LED elements with different light-emitting colors. Multiple second pixel units are arranged in a second region and include multiple second LED elements with different light-emitting colors. In the first LED element and the second LED element with a certain color light, the luminous brightness of the first LED element is greater than that of the second LED element. A package structure covers the multiple first pixel units and the multiple second pixel units. A regulating material for reducing a brightness of the certain color light is arranged in the package structure, and is correspondingly arranged in the first region.

### CROSS-REFERENCE TO RELATED APPLICATION

This application the benefit of priority of China Patent Application No. 202310452906.6, filed on Apr. 24, 2023, the contents of which are incorporated by reference as if fully set forth herein in their entirety.

### TECHNICAL FIELD

The present application relates to the field of display technologies, and in particular, to display panels and joinable display panels.

### BACKGROUND

In the related art, Mini-light-emitting diode (Mini-LED) or Micro-LED lamp beads are generally manufactured in batches, but the luminous brightness and chromaticity of LED lamp beads in different batches are different. In order to ensure the display uniformity of LED panels, the conventional method is to uniformly and mixedly bond the LED lamp beads in different batches onto a lamp board during the bonding process, so as to make the display uniformity in different regions. However, the efficiency of this bonding is too low.

### SUMMARY

Embodiments of the present application provides a display panel and a joinable display panel, which can improve the display uniformity of a light-emitting diode (LED) panel and ensure the efficiency of package.

Some embodiments of the present application provide a display panel, which includes: a driving substrate, including a first region and a second region disposed on at least one side of the first region; multiple first pixel units, arranged in the first region, the multiple first pixel units including multiple first light-emitting diode (LED) elements with different light-emitting colors; multiple second pixel units, arranged in the second region, the multiple second pixel units including multiple second LED elements with different light-emitting colors; wherein a luminous brightness of the first LED element is greater than a luminous brightness of the second LED element in the first LED element and the second LED element with a certain color light; and a package structure, arranged on the driving substrate and covering the multiple first pixel units and the multiple second pixel units; wherein the package structure is provided with a regulating material configured (i.e., structured and arranged) to reduce a brightness of the certain color light, and the regulating material is correspondingly disposed in the first region.

In some embodiments of the present application, the package structure includes an adhesive layer, a water-blocking layer and a protective layer; the adhesive layer covers the multiple first pixel units and the multiple second pixel units, the water-blocking layer is disposed on a side of the adhesive layer away from the driving substrate, and the protective layer is disposed on a side of the water-blocking layer away from the adhesive layer.

The regulating material is disposed in at least one of the water-blocking layer and the protective layer.

In some embodiments of the present application, the package structure includes a package glue layer, an adhesive layer, a water-blocking layer and a protective layer; the package glue layer covers the multiple first pixel units and the multiple second pixel units, the adhesive layer is disposed on a side of the package glue layer away from the driving substrate, the water-blocking layer is disposed on a side of the adhesive layer away from the package glue layer, and the protective layer is disposed on the water-blocking layer away from the adhesive layer.

The regulating material is disposed in at least one of the package glue layer, the water-blocking layer and the protective layer.

In some embodiments of the present application, the multiple first pixel units and the multiple second pixel units emit three kinds of colors of light; the brightness of any two colors of light selected from the three kinds of colors of light among the multiple first pixel units and the multiple second pixel units is the same, and the brightness of a third color of light of the three kinds of colors of light emitted by the first pixel unit is greater than that of the third color of light emitted by the second pixel unit.

The regulating material includes a mixed pigment of the any two colors selected from the three kinds of colors.

In some embodiments of the present application, the multiple the first LED elements include a first red LED element, a first green LED element and a first blue LED element, and the multiple the second LED elements include a second red LED element, a second green LED element and a second blue LED element.

The luminous brightness of the first red LED element is equal to that of the second red LED element, the brightness luminous of the first green LED element is equal to that of the second green LED element, and the luminous brightness of the first blue LED element is greater than that of the second blue LED element.

The regulating material is a mixed pigment of a green pigment and a red pigment or is a yellow pigment.

In some embodiments of the present application, the multiple the first LED elements include a first red LED element, a first green LED element and a first blue LED element, and the multiple the second LED elements include a second red LED element, a second green LED element and a second blue LED element.

The luminous brightness of the first red LED element is equal to that of the second red LED element, the luminous brightness of the first green LED element is greater than that of the second green LED element, and the luminous brightness of the first blue LED element is equal to that of the second blue LED element.

The regulating material is a mixed pigment of a blue pigment and the red pigment.

In some embodiments of the present application, the multiple the first LED elements include a first red LED element, a first green LED element and a first blue LED element, and the multiple the second LED elements include a second red LED element, a second green LED element and a second blue LED element.

The luminous brightness of the first red LED element is greater than that of the second red LED element, the luminous brightness of the first green LED element is equal to that of the second green LED element, and the luminous brightness of the first blue LED element is equal to that of the second blue LED element.

The regulating material is a mixed pigment of the blue pigment and the green pigment.

In some embodiments of the present application, when the regulating material is the mixed pigment of the blue pigment and the red pigment, a mass of the mixed pigment of the blue pigment and the red pigment accounts for 5%-10% of a mass of a film layer provided with the mixed pigment.

In some embodiments of the present application, the yellow pigment incudes at least one of anthraquinones, benzimidazolones, azo and benzidine yellow, the green pigment incudes at least one of halogenated copper phthalocyanines and phthalocyanines, the red pigment comprises at least one of the anthraquinones, pyrrole and pyrrolones, perylene pigment, quinacridone and derivatives, and the blue pigment incudes at least one of copper phthalocyanine and the anthraquinones.

In some embodiments of the present application, the multiple first pixel units and the multiple second pixel units emit three kinds of colors of light; the brightness of a first color of light of the three kinds of colors of light among the multiple first pixel units and the multiple second pixel units is the same; the brightness of a second color of light, emitted by the first pixel unit, of the three kinds of colors of light is greater than that of the second color light emitted by the second pixel unit; and the brightness of a third color of light, emitted by the first pixel unit, of the three kinds of colors of light is smaller than that of the third color light emitted by the second pixel unit.

The regulating material includes up-conversion particles, and the up-conversion particles are configured to absorb the second color of light and emit the third color of light.

In some embodiments of the present application, the multiple the first LED elements include a first red LED element, a first green LED element and a first blue LED element, and the multiple the second LED elements include a second red LED element, a second green LED element and a second blue LED element.

The luminous brightness of the first red LED element is smaller than that of the second red LED element, the luminous brightness of the first green LED element is equal to that of the second green LED element, and the luminous brightness of the first blue LED element is greater than that of the second blue LED element; or, the luminous brightness of the first red LED element is smaller than that of the second red LED element, the luminous brightness of the first green LED element is greater than that of the second green LED element, and the luminous brightness of the first blue LED element is equal to that of the second blue LED element.

The regulating material includes red quantum dots.

In some embodiments of the present application, the multiple the first LED elements include a first red LED element, a first green LED element and a first blue LED element, and the multiple the second LED elements include a second red LED element, a second green LED element and a second blue LED element.

The luminous brightness of the first red LED element is equal to that of the second red LED element, the luminous brightness of the first green LED element is smaller than that of the second green LED element, and the luminous brightness of the first blue LED element is greater than that of the second blue LED element.

The regulating material includes green quantum dots.

In some embodiments of the present application, the multiple the first LED elements include a first red LED element, a first green LED element and a first blue LED element, and the multiple the second LED elements include a second red LED element, a second green LED element and a second blue LED element.

The luminous brightness of the first red LED element is greater than that of the second red LED element, the luminous brightness of the first green LED element is equal to that of the second green LED element, and the luminous brightness of the first blue LED element is smaller than that of the second blue LED element.

The regulating material includes the up-conversion particles, and the up-conversion particles are configured absorb red light and emit blue light.

Correspondingly, some embodiments of the present application also provide a joinable display panel, which includes at least two display panels according to any one of the above embodiments, and at least two display panels are joined together.

The embodiments of the present application adopt the display panel, which includes the driving substrate, the multiple first pixel units, the multiple second pixel units and the package structure. The driving substrate includes the first region and the second region disposed on at least one side of the first region. The multiple first pixel units are arranged in the first region, and the multiple first pixel units include multiple first LED elements with different light-emitting colors. The multiple second pixel units are arranged in the second region, and the multiple second pixel units include multiple second LED elements with different light-emitting colors. Among the first LED element and the second LED element with the certain color light, the luminous brightness of the first LED element is greater than that of the second LED element. The package structure is arranged on the driving substrate and covers the multiple first pixel units and the multiple second pixel units, and the regulating material used to reduce the luminous brightness of the certain color light is arranged in the package structure, and the regulating material is correspondingly arranged in the first region.

In the present application, the first pixel units are arranged in the first region, and the second pixel units are arranged in the second region, which is convenient for centralized bonding and improves the efficiency of bonding compared with the mixed bonding. In addition, the whole LED board is packaged by the package structure with the regulating material, which not only achieves the packaging effect, but also adjusts the color brightness of the first region through the regulating material, so that the color brightness of the first region and the color brightness of the second region tend to be consistent, thus improving the display uniformity of the panel.

### BRIEF DESCRIPTION OF THE DRAWINGS

FIG. 1 is a schematic structural view of a first kind of display panel according to some embodiments of the present application.

FIG. 2 is a schematic structural view of a second kind of display panel according to some embodiments of the present application.

FIG. 3 is a schematic structural view of a third kind of display panel according to some embodiments of the present application.

FIG. 4 is a schematic structural view of a fourth kind of display panel according to some embodiments of the present application.

FIG. 5 is a schematic structural view of a fifth kind of display panel according to some embodiments of the present application.

FIG. 6 is a schematic structural view of a sixth kind of display panel according to some embodiments of the present application.

### DETAILED DESCRIPTION

Technical solutions in embodiments of the present application will be clearly and completely described below with reference to the accompanying drawings in the embodiments of the present application. Apparently, the illustrated embodiments are only some of the embodiments of the present application, but not all of them. Based on the embodiments in the present application, all other embodiments obtained by those skilled in the art without creative work belong to the protection scope of the present application. In addition, it should be understood that the specific embodiments described herein are only used to illustrate and explain the present application, and are not used to limit this present application. In the present application, unless otherwise stated, directional terms such as “up” and “down” usually refer to the up and down in an actual use or working condition of the device, specifically in a direction of figure in the accompanying drawings; and “inside” and “outside” refer to an outline of the device.

Embodiments of the present application provide a display panel and a joinable display panel, which are described in detail below. It should be noted that the description order of the following embodiments is not taken as a limitation to a preferred order of the embodiments.

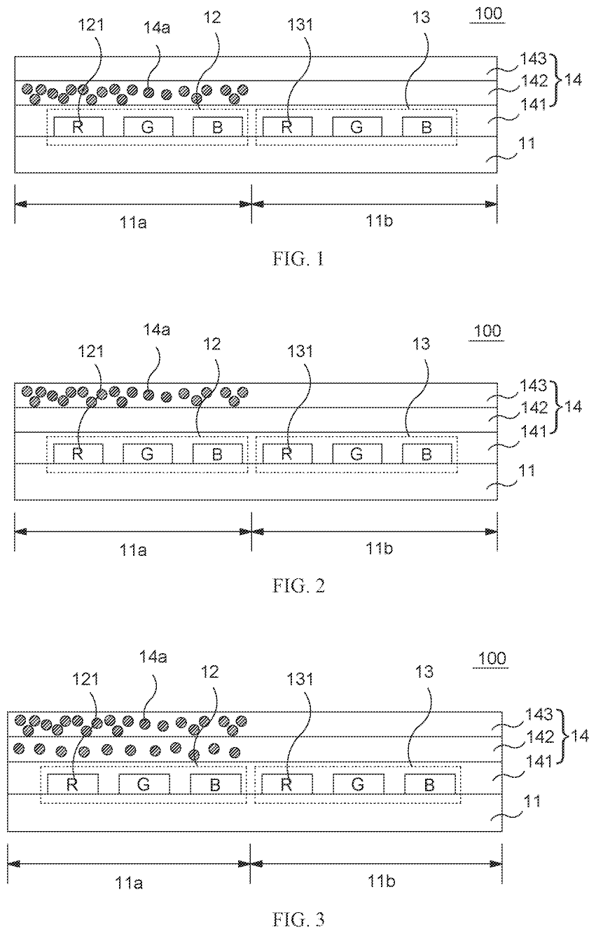

Referring to FIG. 1, some embodiments of the present application provide a display panel 100, which includes a driving substrate 11, multiple first pixel units 12, multiple second pixel units 13, and a package structure 14.

The driving substrate 11 includes a first region 11a and a second region 11b disposed on at least one side of the first region 11a. The multiple first pixel units 12 are disposed in the first region 11a. The first pixel units 12 include multiple first LED elements 121 with different light-emitting colors. The multiple second pixel units 13 are disposed in the second region 11b. The second pixel units 13 include multiple second LED elements 131 with different light-emitting colors. In the first LED element 121 and the second LED element 131 with a certain color of light, the luminous brightness of the first LED element 121 is greater than that of the second LED element 131. The package structure 14 is disposed on the driving substrate 11 and covers the multiple first pixel units 12 and the multiple second pixel units 13. The package structure is provided with a regulating material 14a configured (i.e., structured and arranged) to reduce the luminous brightness of the certain color of light, and the regulating material is correspondingly disposed in the first region 11a.

In the present application, the first pixel units 12 are arranged in the first region 11a and the second pixel units 13 are arranged in the second region 11b, which is convenient for centralized bonding and improves the efficiency of bonding compared with mixed bonding. In addition, the whole LED board is packaged by the package structure 14 provided with the regulating material 14a, which not only achieves the packaging effect, but also adjusts the color brightness of the first region 11a through the regulating material 14a, so that the color brightness of the first region 11a and the color brightness of the second region 11b tend to be consistent, thereby improving the display uniformity of panel.

It can be understood that, generally, the luminous brightness and chromaticity of LED elements emitting light of the same color in the same batch are similar or the same; and there is a certain difference between the luminous brightness and chromaticity of different batches of LED elements emitting light of the same color light. In this case, if one batch of LED elements is set in one region and the other batch of LED elements is set in another region, there will be a great difference between the luminous brightness and chromaticity of the two regions, resulting in poor display uniformity.

In the present application, the regulating material 14a is added into the package structure 14 to adjust the brightness and chromaticity of the first region to the brightness and chromaticity of the second region, so as to improve the display uniformity.

In an embodiment, the driving substrate 11 includes a substrate and a driving circuit structure layer disposed on the substrate. The driving circuit in the driving circuit structure layer is used to drive the LED elements (the first LED elements 121 and the second LED elements 131) to emit light.

In an embodiment, the package structure 14 includes an adhesive layer 141, a water-blocking layer 142 and a protective layer 143. The adhesive layer 141 covers the multiple first pixel units 12 and the multiple second pixel units 13. The water-blocking layer 142 is disposed on a side of the adhesive layer 141 away from the driving substrate 11. The protective layer 143 is disposed on a side of the water-blocking layer 142 away from the adhesive layer 141.

The regulating material 14a is disposed in at least one of the water-blocking layers 142 and the protective layer 143.

The adhesive layer 141 is used to attach to the driving substrate 11 and the first- and second-pixel units 12 and 13. The water-blocking layer 142 plays a role in preventing water and oxygen intrusion. The protective layer 143 is not only used to protect the water-blocking layer 142, but also serves as a substrate in the process of preparing to support the package structure 14.

In an embodiment, the regulating material 14a may be disposed in the water-blocking layer 142, as shown in FIG. 1.

In some embodiments, as shown in FIG. 2, the regulating material 14a may also be disposed in the protective layer 143.

In some embodiments, as shown in FIG. 3, the regulating material 14a may also be disposed in both the water-blocking layer 142 and the protective layer 143. Specifically, a mass ratio of the regulating material 14a disposed in the water-blocking layer 142 is smaller than that of the regulating material 14a disposed in the protective layer 143. That is, the amount of regulating material 14a disposed in the water-blocking layer 142 is smaller than that of the regulating material 14a disposed in the protective layer 143.

It can be understood that the mass ratio of regulating material 14a refers to the ratio of the mass of all regulating material 14a in a certain film layer to the mass of the film layer. A small amount of regulating material 14a is disposed in the water-blocking layer 142 to ensure the water-oxygen blocking effect of the water-blocking layer 142. Since the regulating material 14a can promote the crystallization of the protective layer 143 and increase the number of crystal grains to a certain extent, the tensile strength and impact strength of the protective layer 143 can be improved by disposing a large amount of the regulating material 14a in the protective layer 143. Therefore, different mass ratios of the regulating material 14a are correspondingly arranged on the film layers with different functions, which not only achieves the effect of regulating brightness and chromaticity, but also improves the performance of each functional film layer.

In some embodiments, as shown in FIG. 4, the package structure 14 includes a package glue layer 144, an adhesive layer 141, a water-blocking layer 142 and a protective layer 143. The package glue layer 144 covers the multiple first pixel units 12 and the multiple second pixel units 13. The adhesive layer 141 is disposed on the side of the package glue layer 144 away from the driving substrate 11, and the water-blocking layer 142 is disposed on the side of the adhesive layer 141 away from the package glue layer 144. The protective layer 143 is disposed on the side of the water-blocking layer 142 away from the adhesive layer 141.

The regulating material 14a is disposed in at least one of the package glue layers 144, the water-blocking layer 142 and the protective layer 143.

In this embodiment, the regulating material 14a is disposed in the package glue layer 144.

In some embodiments, the regulating material 14a may also be separately disposed on the water-blocking layer 142 and the protective layer 143.

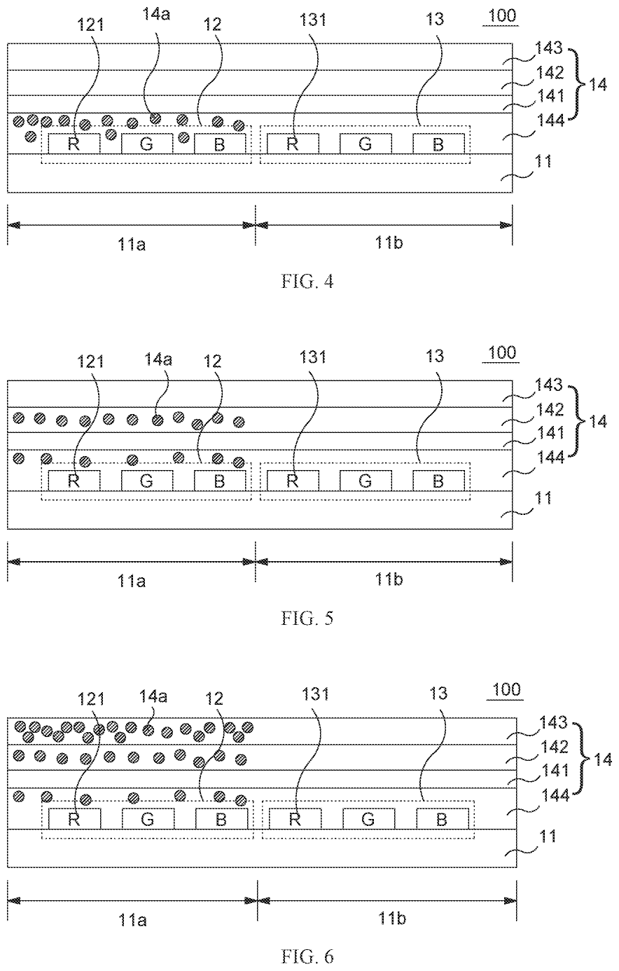

In some embodiments, as shown in FIG. 5, the regulating material 14a may also be simultaneously disposed in two of the package glue layer 144, the water-blocking layer 142 and the protective layer 143, such as the package glue layer 144 and the water-blocking layer 142, the package glue layer 144 and the protective layer 143, or the water-blocking layer 142 and the protective layer 143. Specifically, the mass ratio of the regulating material 14a to the protective layer 143 is greater than that of the regulating material 14a to the water-blocking layer 142 and greater than that of the regulating material 14a to the package glue layer 144 individually.

In some embodiments, as shown in FIG. 6, the regulating material 14a may also be simultaneously disposed in the package glue layer 144, the water-blocking layer 142 and the protective layer 143. The mass ratio of the regulating material 14a is incremented in the direction from the package glue layer 144 to the protective layer 143.

In an embodiment, the material of the protective layer 143 may include one of silicon dioxide, polyethylene, polypropylene, polystyrene, polylactic acid, polyethylene dicarboxylate, polyethylene terephthalate (also referred to as polyethylene glycol terephthalate or PET), polyethylene naphthalate two formic acid glycol ester (also referred to as polyethylene naphthalate or PEN), polycarbonate, polyethersulfone, aromatic fluorotoluene containing polyarylate, polycyclic olefin, polyimide or polyurethane.

In an embodiment, the first pixel units 12 and the second pixel units 13 emit three kinds of colors of light. The brightness of any two colors of light is the same among the first pixel unit 12 and the second pixel unit 13, and the brightness of a third color of light emitted by the first pixel unit 12 is greater than that of the third color light emitted by the second pixel unit 13.

The regulating material 14a includes a mixed pigment of any two colors selected from the three kinds of colors.

Since among the three kinds of colors of light, only one color of light is different. Therefore, the regulating material 14a may be selected from pigments with the same colors as the other two colors to absorb the third color of light with greater brightness, so as to achieve white balance and/or achieve the same brightness and chromaticity of the three colors.

In an embodiment, when the blue light brightness of the first pixel units 12 is greater than that of the second pixel units 13, the multiple first LED elements 121 include a first red LED element, a first green LED element, and a first blue LED element. The multiple second LED elements 131 includes a second red LED element, a second green LED element, and a second blue LED element.

The luminous brightness of the first red LED element is equal to that of the second red LED element, the luminous brightness of the first green LED element is equal to that of the second green LED element, and the luminous brightness of the first blue LED element is greater than that of the second blue LED element.

The regulating material 14a is a mixed pigment of a green pigment and a red pigment; or the regulating material 14a is a yellow pigment. Due to the high blue light, the red and green pigments are used to absorb part of the blue light, so that the brightness and chromaticity of the blue light in the first region 11a and the second region 11b tend to be the same.

In an embodiment, when the green brightness of the first pixel units 12 is greater than that of the second pixel units 13, the luminous brightness of the first red LED element is equal to that of the second red LED element, the luminous brightness of the first green LED element is greater than that of the second green LED element, and the luminous brightness of the first blue LED element is equal to that of the second blue LED element.

The regulating material 14a is a mixed pigment of a blue pigment and the red pigment. Due to the high green light in the first region 11a, the red and blue pigments are used to absorb part of the green light, so that the brightness and chromaticity of the green light in the first region 11a and the second region 11b tend to be the same.

For example, the chromaticity (x, y) and brightness specifications of the first red LED element are (0.692, 0.315, 0.247), the chromaticity and brightness specifications of the first green LED element are (0.205, 0.744, 0.765), and the chromaticity and brightness specifications of the first blue LED element are (0.141, 0.044, 0.055). The chromaticity and brightness specifications of the second red LED element are (0.692, 0.315, 0.247), the chromaticity and brightness specifications of the second green LED element is (0.206, 0.743, 0.704), and the chromaticity and brightness specifications of the second blue LED element is (0.141, 0.044, 0.055).

In this situation, the mass of the mixed pigment of blue pigment and red pigment accounts for 5%-10% of the mass of the film layer provided with the mixed pigment. The higher the proportion, the better the effect of absorbing green light.

In an embodiment, when the red brightness of the first pixel units 12 is greater that of the second pixel units 13, the luminous brightness of the first red LED element is greater than that of the second red LED element, the luminous brightness of the first green LED element is equal to that of the second green LED element, and the luminous brightness of the first blue LED element is equal to that of the second blue LED element.

The regulating material 14a is a mixed pigment of the blue pigment and the green pigment. Due to the high red light in the first region 11a, the blue and green pigments are used to absorb part of the red light, so that the brightness and chromaticity of the red light in the first region 11a and the second region 11b tend to be the same.

In an embodiment, the yellow pigment may be anthraquinones, such as PY147/PY177/PY24P; benzimidazolones, such as PY154; azo, such as Hansa® Yellow 10G, benzidine yellow, etc. The green pigment may be halogenated copper phthalocyanines such as PG7 and PG36, and phthalocyanines such as PG58. The red pigment may be anthraquinones, such as PR177/PR168//PR83/PR216/PR226; pyrrole and pyrrolones, such as PR254/PR255/PR264/PR272; perylene pigments such as PR179/PR244/PR90/PR123/PR149; quinacridone and derivatives, such as PR122/PR202/PR209. The blue pigment may be copper phthalocyanine, such as B15:6; anthraquinones, such as PB60/PB64/PB21/PB22/PB65.

In some embodiments, the first pixel units 12 and the second pixel units 13 emit three kinds of colors of light. The brightness of the first color of lights is the same among the first pixel units 12 and the second pixel units 13, and the brightness of the second color of light emitted by the first pixel units 12 is greater than that of the second color of light emitted by the second pixel units 13. The brightness of the third color of light emitted by the first pixel units 12 is smaller than that of the third color light emitted by the second pixel units 13.

The regulating material 14a includes up-conversion particles used to absorb the second color of light and emitting the third color of light.

Among the three kinds of colors of light, the brightness of one color is the same, while the other two colors are different. Between the two different colors of light, the brightness of the second color of light of the first pixel units 12 is greater than that of the second color of light of the second pixel units 13, and the brightness of the third color of light of the first pixel units 12 is smaller than that of the second pixel units 13. In this case, the higher brightness color may be used to compensate for the lower brightness color, so that that brightness region of light of each color are the same.

In an embodiment, compared with the second pixel units 13, the first pixel units 12 have a higher blue brightness or green brightness and a lower red brightness.

The luminous brightness of the first red LED element is smaller than that of the second red LED element, the luminous brightness of the first green LED element is equal to that of the second green LED element, and the luminous brightness of the first blue LED element is greater than that of the second blue LED element; or, the luminous brightness of the first red LED element is smaller than that of the second red LED element, the luminous brightness of the first green LED element is greater than that of the second green LED element, and the luminous brightness of the first blue LED element is equal to that of the second blue LED element.

The regulating material 14a includes red quantum dots. The red quantum dots are excited by blue light to emit red light, so as to reduce the blue light with higher brightness and improve the red light with lower brightness, so that the brightness of each color tends to be consistent.

In an embodiment, compared with the second pixel units 13, the first pixel units 12 have a higher blue brightness and a lower green brightness.

The luminous brightness of the first red LED element is equal to that of the second red LED element. The luminous brightness of the first green LED element is smaller than that of the second green LED element. The luminous brightness of the first blue LED element is greater than that of the second blue LED element.

The regulating material 14a includes green quantum dots. The green quantum dots are excited by blue light to emit green light, so as to reduce the blue light with higher brightness and improve the green light with lower brightness, so that the brightness of each color tends to be consistent.

In an embodiment, compared with the second pixel units 13, the first pixel units 12 have a higher red brightness and a lower blue brightness.

The luminous brightness of the first red LED element is greater than that of the second red LED element. The luminous brightness of the first green LED element is equal to that of the second green LED element. The luminous brightness of the first blue LED element is smaller than that of the second blue LED element.

The regulating material 14a includes up-conversion particles used to absorb red light and emit blue light.

In an embodiment, the up-conversion particles may be Tm-doped NaGdF4 nanoparticles.

In summary, in this present application, the regulating material 14a is arranged in the package structure 14, so that the color light with higher brightness is reduced to be consistent with the brightness of the same color light in another region, thereby improving the display uniformity.

Correspondingly, the embodiments of the present application also provides a joinable display panel, which includes at least two display panels, and the display panels are joined together. The display panel of the joinable display panel is the display panel 100 of any of the above embodiments.

Since the display panel of this embodiments is the display panel 100 of any of the above embodiments, it will not be described in detail herein.

The display panel provided by the embodiments of the present application is described in detail above, and the principle and implementation of the present application are described with specific embodiments herein. The description of the above embodiments is only used to help understand the method and core idea of the present application. In this situation, according to the idea of the present application, there will be changes in the specific implementation and application scope for those skilled in this field. In conclusion, the contents of this specification should not be understood as limitations on the present application.

What is claimed is:

1. A display panel, comprising:
a driving substrate, comprising a first region and a second region disposed on at least one side of the first region;
a plurality of first pixel units, arranged in the first region, the plurality of first pixel units comprise a plurality of first LED elements with different light-emitting colors;
a plurality of second pixel units, arranged in the second region, the plurality of second pixel units comprise a plurality of second LED elements with the different light-emitting colors; a luminous brightness of the first LED element is greater than that of the second LED element in the first LED element and the second LED element with a certain color of light; and
a package structure, arranged on the driving substrate and covering the plurality of first pixel units and the plurality of second pixel units; the package structure is provided with a regulating material configured to reduce a brightness of the certain color of light, and the regulating material is correspondingly disposed in the first region.

2. The display panel of claim 1, wherein the package structure comprises an adhesive layer, a water-blocking layer and a protective layer; the adhesive layer covers the plurality of first pixel units and the plurality of second pixel units, the water-blocking layer is disposed on a side of the adhesive layer away from the driving substrate, and the protective layer is disposed on a side of the water-blocking layer away from the adhesive layer; and the regulating material is disposed in at least one of the water-blocking layer and the protective layer.

3. The display panel of claim 1, wherein the package structure comprises a package glue layer, an adhesive layer, a water-blocking layer and a protective layer; the package glue layer covers the plurality of first pixel units and the plurality of second pixel units, the adhesive layer is disposed on a side of the package glue layer away from the driving substrate, the water-blocking layer is disposed on a side of the adhesive layer away from the package glue layer, and the protective layer is disposed on the water-blocking layer away from the adhesive layer; and the regulating material is disposed in at least one of the package glue layer, the water-blocking layer and the protective layer.

4. The display panel of claim 2, wherein the plurality of first pixel units and the plurality of second pixel units emit three kinds of colors of light; the brightness of any two colors of light selected from the three kinds of colors of light among the plurality of first pixel units and the plurality of second pixel units is the same, and the brightness of a third color of light of the three kinds of colors of light emitted by the first pixel unit is greater than that of the third color of light emitted by the second pixel unit; and the regulating material comprises a mixed pigment of the any two colors selected from the three kinds of colors.

5. The display panel of claim 4, wherein the plurality of the first LED elements comprises a first red LED element, a first green LED element and a first blue LED element, and the plurality of the second LED elements comprise a second red LED element, a second green LED element and a second blue LED element;
the luminous brightness of the first red LED element is equal to that of the second red LED element, the brightness luminous of the first green LED element is equal to that of the second green LED element, and the luminous brightness of the first blue LED element is greater than that of the second blue LED element; and the regulating material is a mixed pigment of a green pigment and a red pigment or is a yellow pigment; or
the luminous brightness of the first red LED element is equal to that of the second red LED element, the luminous brightness of the first green LED element is greater than that of the second green LED element, and the luminous brightness of the first blue LED element is equal to that of the second blue LED element; and the regulating material is a mixed pigment of a blue pigment and the red pigment; or
the luminous brightness of the first red LED element is greater than that of the second red LED element, the luminous brightness of the first green LED element is equal to that of the second green LED element, and the luminous brightness of the first blue LED element is equal to that of the second blue LED element; and the regulating material is a mixed pigment of the blue pigment and the green pigment.

6. The display panel of claim 5, wherein when the regulating material is the mixed pigment of the blue pigment and the red pigment, a mass of the mixed pigment of the blue pigment and the red pigment accounts for 5%-10% of a mass of a film layer provided with the mixed pigment.

7. The display panel of claim 5, wherein the yellow pigment comprises at least one of anthraquinones, benzimidazolones, azo and benzidine yellow, the green pigment comprises at least one of halogenated copper phthalocyanines and phthalocyanines, the red pigment comprises at least one of the anthraquinones, pyrrole and pyrrolones, perylene pigment, quinacridone and derivatives, and the blue pigment comprises at least one of copper phthalocyanine and the anthraquinones.

8. The display panel of claim 2, wherein the plurality of first pixel units and the plurality of second pixel units emit three kinds of colors of light; among the plurality of first pixel units and the plurality of second pixel units, the brightness of a first color of light of the three kinds of colors of light is the same; the brightness of a second color of light, emitted by the first pixel unit, of the three kinds of colors of light is greater than that of the second color light emitted by the second pixel unit; and the brightness of a third color of light, emitted by the first pixel unit, of the three kinds of colors of light is smaller than that of the third color light emitted by the second pixel unit;
the regulating material comprises up-conversion particles, and the up-conversion particles are configured to absorb the second color of light and emit the third color of light.

9. The display panel of claim 8, wherein the plurality of the first LED elements comprises a first red LED element, a first green LED element and a first blue LED element, and the plurality of the second LED elements comprise a second red LED element, a second green LED element and a second blue LED element;
the luminous brightness of the first red LED element is smaller than that of the second red LED element, the luminous brightness of the first green LED element is equal to that of the second green LED element, and the luminous brightness of the first blue LED element is greater than that of the second blue LED element; or, the luminous brightness of the first red LED element is smaller than that of the second red LED element, the luminous brightness of the first green LED element is greater than that of the second green LED element, and the luminous brightness of the first blue LED element is equal to that of the second blue LED element; and the regulating material comprises red quantum dots; or
the luminous brightness of the first red LED element is equal to that of the second red LED element, the luminous brightness of the first green LED element is smaller than that of the second green LED element, and the luminous brightness of the first blue LED element is greater than that of the second blue LED element; and the regulating material comprises green quantum dots; or
the luminous brightness of the first red LED element is greater than that of the second red LED element, the luminous brightness of the first green LED element is equal to that of the second green LED element, and the luminous brightness of the first blue LED element is smaller than that of the second blue LED element;
and the regulating material comprises the up-conversion particles, and the up-conversion particles are configured absorb red light and emit blue light.

10. A joinable display panel, comprising at least two display panels of claim 1, wherein the at least two display panels are joined together.

11. The display panel of claim 3, wherein the plurality of first pixel units and the plurality of second pixel units emit three kinds of colors of light; the brightness of any two colors of light selected from the three kinds of colors of light among the plurality of first pixel units and the plurality of second pixel units is the same, and the brightness of a third color of light of the three kinds of colors of light emitted by the first pixel unit is greater than that of the third color of light emitted by the second pixel unit; and
the regulating material comprises a mixed pigment of the any two colors selected from the three kinds of colors.

12. The display panel of claim 3, wherein the plurality of first pixel units and the plurality of second pixel units emit three kinds of colors of light; among the plurality of first pixel units and the plurality of second pixel units, the brightness of a first color of light of the three kinds of colors of light is the same; the brightness of a second color of light, emitted by the first pixel unit, of the three kinds of colors of light is greater than that of the second color light emitted by the second pixel unit; and the brightness of a third color of light, emitted by the first pixel unit, of the three kinds of colors of light is smaller than that of the third color light emitted by the second pixel unit;
the regulating material comprises up-conversion particles, and the up-conversion particles are configured to absorb the second color of light and emit the third color of light.

13. A joinable display panel, comprising at least two display panels of claim 2, wherein the at least two display panels are joined together.

14. A joinable display panel, comprising at least two display panels of claim 3, wherein the at least two display panels are joined together.

15. A joinable display panel, comprising at least two display panels of claim 4, wherein the at least two display panels are joined together.

16. A joinable display panel, comprising at least two display panels of claim 5, wherein the at least two display panels are joined together.

17. A joinable display panel, comprising at least two display panels of claim 6, wherein the at least two display panels are joined together.

18. A joinable display panel, comprising at least two display panels of claim 7, wherein the at least two display panels are joined together.

19. A joinable display panel, comprising at least two display panels of claim 8, wherein the at least two display panels are joined together.

20. A joinable display panel, comprising at least two display panels of claim 9, wherein the at least two display panels are joined together.
